(19) United States
(12) Patent Application Publication
(10) Pub. No.: US 2010/0283029 A1
(43) Pub. Date: Nov. 11, 2010

(54) Programmable resistance memory and method of making same

(76) Inventors: Charles Dennison, San Jose, CA (US); Wolodymyr Czubatyj, Warren, MI (US); Jeff Fournier, Livonia, MI (US); Tom Latowski, Macomb, MI (US); James Reed, Auburn Hills, MI (US); Regino Sandoval, Rochester Hills, MI (US)

Correspondence Address: Ovonyx, Inc, 2956 Waterview Drive, Rochester Hills, MI, 48309, US

(21) Appl. No.: 12/454,002

(22) Filed: May 11, 2009

(51) Int. Cl. H01L 45/00; H01L 21/06; H01L 21/20

(52) U.S. Cl. 257/3; 438/102; 438/482; 257/E21.068; 257/E21.09; 257/E45.002

(57) ABSTRACT

A memory includes multiple layers of deposited memory material. An etch is performed on at least one layer of deposited memory material prior to the deposition of a subsequent layer of memory material.

### FIELD OF INVENTION

This invention relates to electronic memory devices.

### BACKGROUND OF THE INVENTION

As electronic memories approach limits beyond which they will no longer be able to produce the density/cost/performance improvements so famously set forth in Moore's law, a host of memory technologies are being investigated as potential replacements for conventional silicon complementary metal oxide semiconductor (CMOS) integrated circuit memories. Among the technologies being investigated are programmable resistance technologies, such as phase change memory technologies. Phase-change memory arrays are based upon memory elements that switch among two material phases, or gradations thereof, to exhibit corresponding distinct electrical characteristics. Alloys of elements of group VI of the periodic table, such as Te, S or Se, referred to as chalcogenides or chalcogenic materials, can be used advantageously in phase change memory cells. In some chalcogenide materials, the resistivity varies by two or more orders of magnitude when the material passes from the amorphous (more resistive) phase to the crystalline (more conductive) phase, and vice versa.

A chalcogenide memory device may utilize the wide range of resistance values available for the material as the basis of memory operation, generally bounded by SET and RESET values. By convention, the SET state is a low resistance structural state whose electrical properties are primarily controlled by the crystalline state of the chalcogenide material and the RESET state is a high resistance structural state whose electrical properties are primarily controlled by the amorphous state of the chalcogenide material.

Phase change may be induced by increasing the temperature locally. Typically, below 150° C., both of the phases are reasonably stable. Above 500° C., there is a rapid nucleation of the crystallites and, if the material is kept at the crystallization temperature for a sufficiently long time, it undergoes a phase change and becomes crystalline. To bring the chalcogenide back to the amorphous state it is necessary to raise the temperature above the melting temperature (approximately 600° C. for GST 555, for example) and then cool it off rapidly. An electrical current may establish the requisite crystallization and melting temperatures by Joule effect heating.

Each memory state of a chalcogenide memory material corresponds to a distinct range of resistance values and each memory resistance value range signifies unique informational content. Operationally, the chalcogenide material can be programmed into a particular memory state by providing an electric current pulse of an appropriate amplitude and duration to transform the chalcogenide material into the structural state having the desired resistance. By controlling the amount of energy provided to the chalcogenide material, it is possible to control the relative proportions of crystalline and amorphous phase regions within a volume of the material and to thereby control the structural (and corresponding memory) state of the chalcogenide material to store information. Each memory state can be programmed by providing the current pulse characteristics of the state and each state can be identified, or “read”, in a non-destructive fashion by measuring the resistance of the material. Embodiments in accordance with the principles of the present invention may include binary, ternary, quaternary, and higher order chalcogenide alloys. Chalcogenide materials may be deposited with a reactive sputtering process with gasses such as N2 or O2: forming a chalcogenide nitride, or oxide, for example and chalcogenide may be modified by an ion implantation or other process. Materials may also be deposited using chemical vapor deposition (CVD) processes, for example.

The benefits of a plurality of programmable resistance materials, such as a plurality of phase change memory alloys, may be combined in one device by depositing layers of the different materials in a manner that forms a multi-layered memory device. However, as device geometries shrink, features become more difficult to produce. Depositing multiple layers of phase change material into an opening, such as a pore or microtrench, may be thwarted by artifacts of an earlier-deposited material, such as overhangs, that block proper deposition of later-deposited materials. A multi-layer programmable resistance memory and method for making the same would therefore be highly desirable.

### SUMMARY OF THE INVENTION

In an apparatus and method in accordance with the principles of the present invention, a programmable resistance memory is formed by a series of depositions and at least one etch step, the etch step performed to alter a surface feature of a deposited programmable resistance material and thereby provide an improved surface or structure for a subsequent deposition. In accordance with the principles of the present invention, a first layer of programmable resistance material, such as phase change material, may be deposited into an opening, such as a pore or micro-trench, within a substrate; an etch performed on the first phase change material layer; then another layer of a different phase change material deposited over at least a portion of the first layer of phase change material. The stack of phase change material thus-created forms the core of a phase change memory cell.

The non-planar substrate may, for example, be substantially planar, with openings formed to accept the deposited phase change material. Such openings in the substrate may take the form of pores, vias, micro-trenches or dashes formed within the substrate, for example. Phase change materials may be combined to improve operational characteristics such as cycle life, data retention, RESET current, SET speed, multi-level operation, or resistance drift, for example. Materials having different characteristics may be combined in a manner that emphasizes the performance of one type of phase change material within a region of the memory element within which programming takes place, and emphasizes the characteristics of another type of phase change material outside that “active volume.” For example, a phase change material associated with the active volume may be selected for its fast SET speed, whereas phase change material that is to lie outside the active volume may be selected for its high thermal resistance. Alternatively, materials having different characteristics may be included within the active volume to, for example, improve the multi-level characteristics of a memory.

In accordance with the principles of the present invention, the one or more etch steps performed between phase change deposition steps are directed to modifying surface features of an earlier-deposited phase change material film. Such modifications may include the elimination of overhanging phase change material, or the filling of voids in phase change material that might otherwise prevent good step-coverage for a later-deposited phase change material layer. In accordance with the principles of the present invention various types of etch, including sputter etches and reactive ion etches, may be employed to effect the desired surface modification. Other surface preparation techniques, such as chemical mechanical polishing (CMP), may be employed in a method of producing a phase change memory in accordance with the principles of the present invention.

In an illustrative embodiment, high-resistance phase change material, material which may include Nitrogen or SiO2, for example, is deposited into an opening in a substrate then etched back to produce a desired profile. A different phase change material, having a lower resistance, is then deposited on the etched first layer of phase change material. The higher resistance of the lower layer encourages formation of the active volume within the lower layer. The lower resistance of the upper layer reduces the overall SET resistance of the resultant memory cell. At the same time, the upper layer of phase change material is a better thermal insulator than a top electrode and, as a result, the upper layer of phase change material operates to confine heat to an active volume in the bottom layer and thereby reduce operating current requirements.

Alternatively, a low resistance phase change material may be deposited within an opening, the low resistance material etched back to leave a low resistance layer adjacent the bottom electrode, then a high-resistance phase change material deposited, with the active volume lying within the top layer of phase change material.

The structural, chemical, and electrical characteristics of a multi-layer phase change memory may be optimized, employing at least one etch step, to enhance multi-level memory operation by, for example, producing a structure that diminishes the cell's overall sensitivity to programming current in the transition region between the SET and RESET states. Typically, the transition from the SET to RESET is accomplished by applying a current pulse of only slightly higher magnitude than a pulse that would not affect the state of the device; there is an abrupt change between SET and RESET. Programming the cell to states that are intermediate to the SET and RESET states requires precise control of programming currents. By diminishing the cell's sensitivity to programming current in the transition region, each state between the SET and RESET states may programmed with greater margin. In a multi-layer embodiment, materials featuring varying properties may be deposited in sequence to produce a cell within which the active volume encompasses at least a segment of each of the material layers. A cell that is composed of multiple layers may have a more gradual transition from set to reset resistance as the differing segments of phase change materials become involved in the cell programming thereby providing greater margin for each programmed state.

The programmable resistance materials may be, for example, phase change materials, such as chalcogenide materials and the etch step may be performed in a manner that preferentially etches one or more portions or features of the prior-deposited phase change material (the first-deposited material in a two-material embodiment). Additional deposition and etch steps are contemplated within the scope of the invention.

In embodiments that employ phase change materials, such as chalcogenide materials, the phase change material may be deposited using any of a variety of techniques, including sputtering, physical vapor deposition (PVD), chemical vapor deposition (CVD), atomic vapor deposition (AVD), or atomic layer deposition (ALD), for example.

The openings into which phase change material is deposited may be as small as manufacturing techniques, such as lithographic and other techniques known in the art, permit. In illustrative embodiments a lateral dimension of a pore- or trench-opening may be between 5 and 100 nm. The lateral dimension of such an opening may be engineered to limit the active volume of phase change material within a memory device.

In phase-change embodiments, the different types of phase change materials that are combined in a memory cell in accordance with the principles of the present invention may exhibit differences in characteristics such as thermal conductivity, melt temperature, crystallization growth speed, nucleation rate, data retention, or cycle endurance, for example.

A programmable resistance memory in accordance with the principles of the present invention may be particularly suitable for operation in a variety of electronic devices, including cellular telephones, radio frequency identification devices (RFID), computers (portable and otherwise), solid state drives (SSDs), location devices (e.g., global positioning system (GPS) devices, particularly those that store and update location-specific information), and handheld electronic devices, including personal digital assistants (PDAs), and entertainment devices, such as MP3 players, for example.

### BRIEF DESCRIPTION OF THE DRAWINGS

FIGS. 1A through 1K are profile views of a memory element formed with an opening such as may be employed by a memory element in accordance with the principles of the present invention;

FIG. 2 is profile view of memory element in accordance with the principles of the present invention in which the programmed volume of the material is confined to the first-deposited layer of material;

FIG. 3 is profile view of memory element in accordance with the principles of the present invention in which the programmed volume of the material is confined to the second-deposited layer of material;

FIGS. 4A and 4B are profile a profile view of a multilayer memory in accordance with the principles of the present invention and a related R-I curve, respectively;

FIG. 5 is a block diagram of a memory array, including peripheral circuitry, in accordance with the principles of the present invention; and

FIG. 6 is a block diagram of an electronic system that employs a memory in accordance with the principles of the present invention.

### DETAILED DESCRIPTION

Although this invention will be described in terms of certain preferred embodiments, other embodiments that are apparent to those of ordinary skill in the art, including embodiments that do not provide all of the benefits and features set forth herein, are also within the scope of this invention. Various structural, logical, process step, chemical, and electrical changes may be made without departing from the spirit or scope of the invention. Polarities and types of devices and supplies may be substituted in a manner that would be apparent to one of reasonable skill in the art. Process descriptions may include flowcharts that illustrate various steps taken in a process. Such flowcharts and accompanying discussion are not meant to be an exhaustive explanation of every step and every procedure in such a process. Rather, they are meant to provide a description with sufficient detail to enable one of ordinary skill in the art to practice and use the invention. In some embodiments, additional steps may be employed or steps may be carried out in a different sequence than set forth in the flowchart and associated discussion.

The term “voltage signal” or “voltage pulse signal” is used herein to refer to a signal that is voltage-compliant. That is, the voltage of the signal is regulated to a desired level. Similarly, the term “current signal” or “current pulse signal” is used herein to refer to a signal that is current-compliant; the current of the signal is regulated to a desired level. Although an apparatus and method in accordance with the principles of the present invention may be implemented using any of a variety of programmable resistance materials, for clarity and convenience, the invention will be described in terms of illustrative embodiments that employ phase change materials, such as chalcogenide materials. When reference is made to a layer of material, the layer may be a partial layer; it needn't cover an entire substrate and may be patterned, for example. Features within drawings are not, typically, drawn to scale and the drawings are used for illustrative purposes only. Accordingly, the scope of the invention is defined only by reference to the appended claims.

In an apparatus and method in accordance with the principles of the present invention, a programmable resistance memory is formed by a series of depositions and at least one etch step, the etch step performed to alter surface features of deposited programmable resistance material.

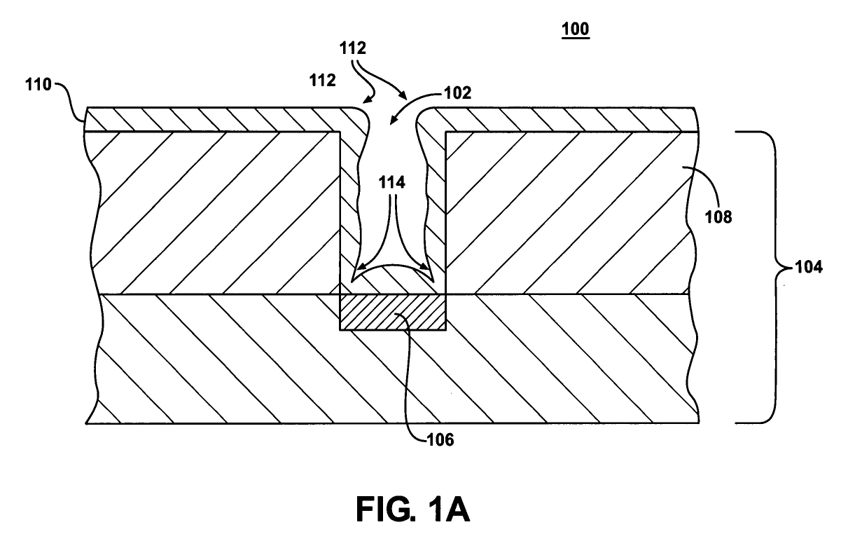

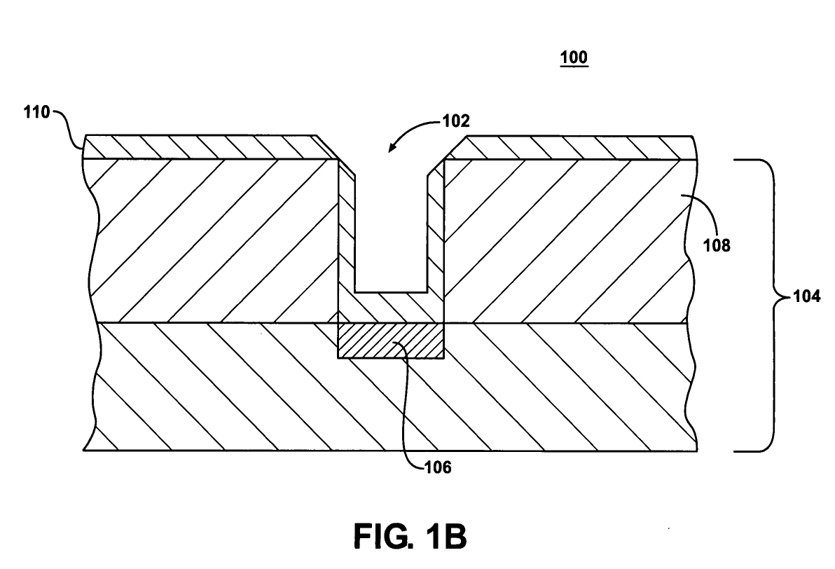

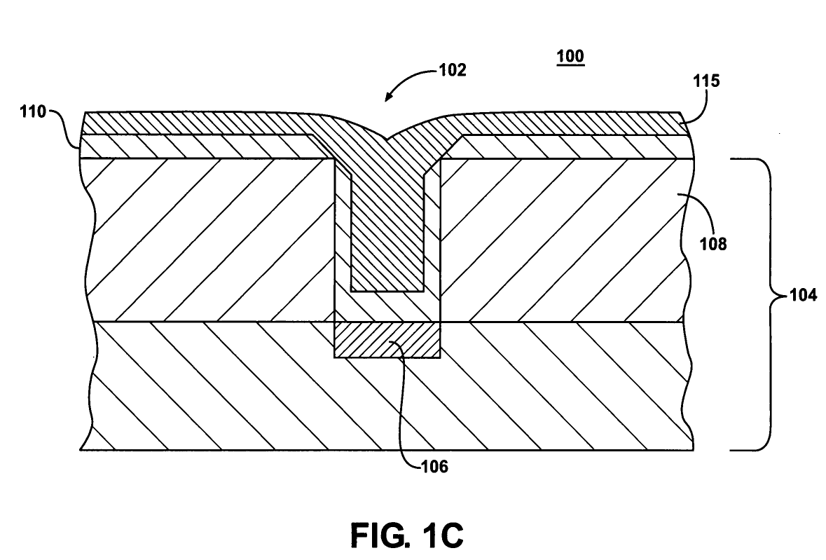

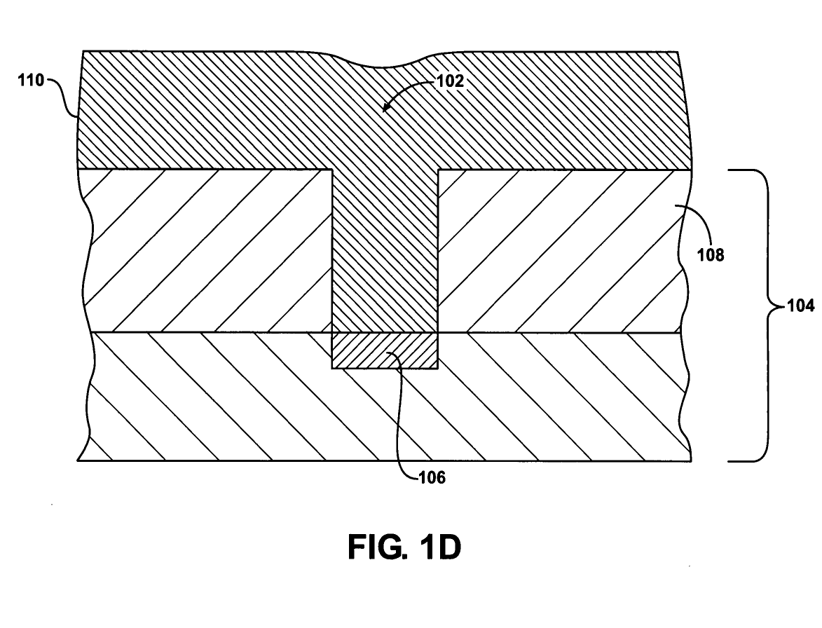

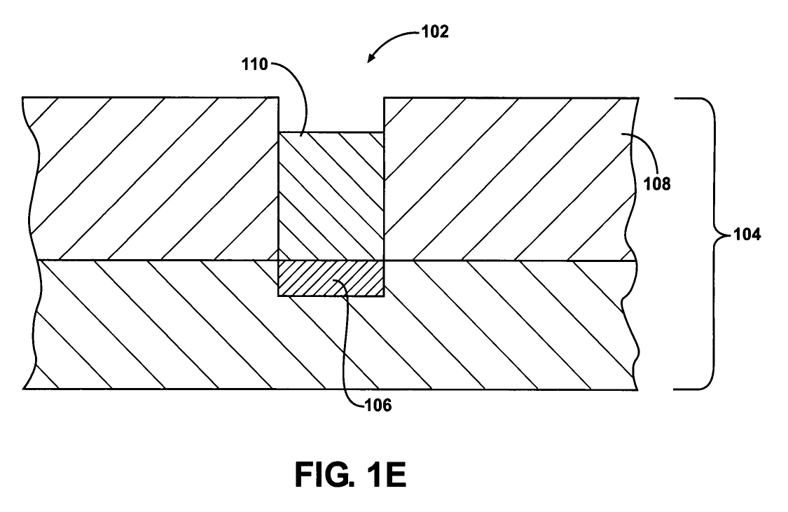

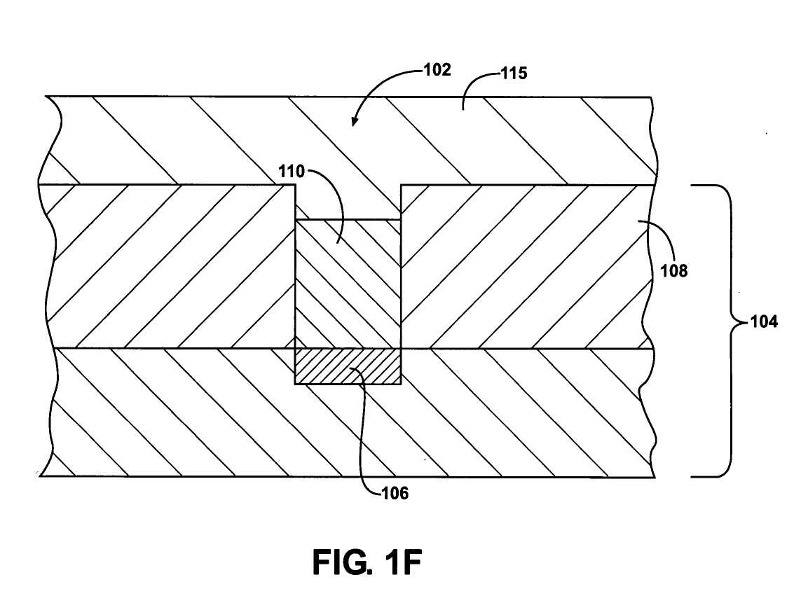

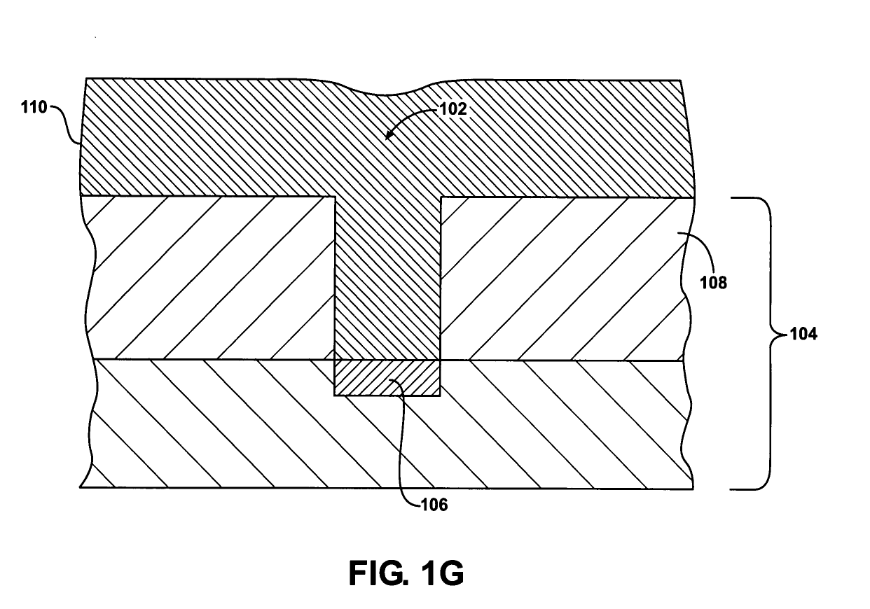

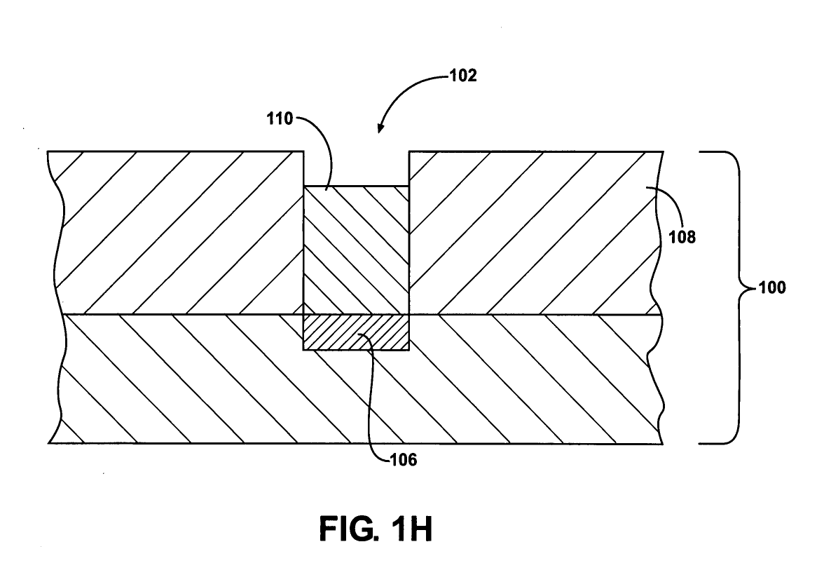

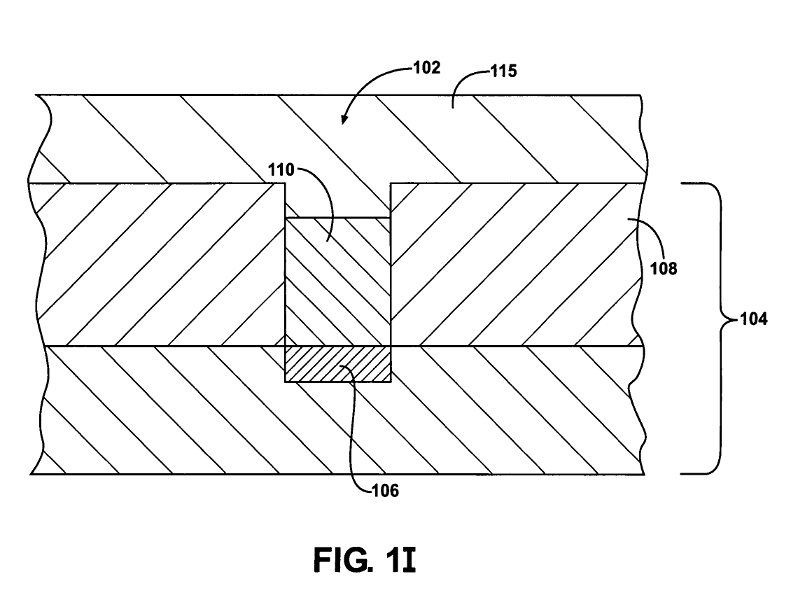

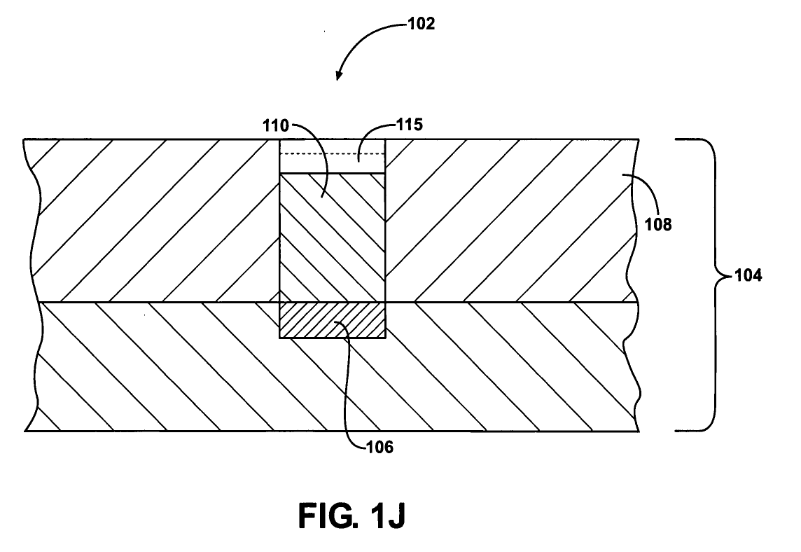

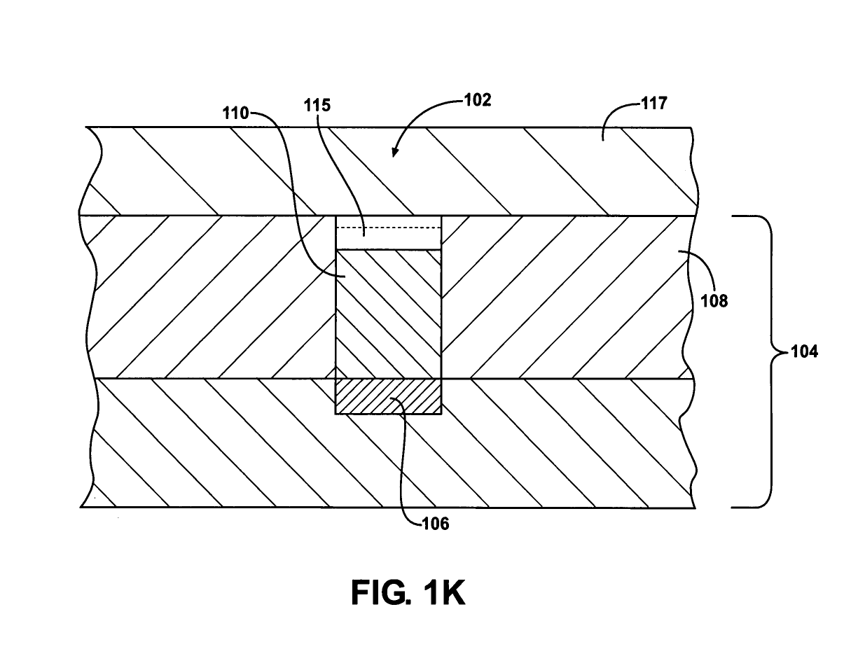

In the illustrative embodiment of FIGS. 1A though 1C a programmable resistance memory element 100 is formed in accordance with the principles of the present invention. An opening 102 is formed in a substrate 104 that includes an underlying circuit element 106. The non-planar substrate may be substantially planar, with openings formed to accept the deposited phase change material. Such openings in the substrate may take the form of pores, vias, micro-trenches or dashes formed within the substrate, for example. The opening 102 may be in the form of a pore or a micro trench, for example, formed within a dielectric layer 108. One or more lateral dimensions of the opening 102 may be as small as manufacturing techniques permit. In illustrative embodiments a lateral dimension of a pore- or trench-opening may be between 5 and 100 nm, preferably, between 5 nm and 50 nm, more preferably, between 5 nm and 35 nm. One or more lateral dimensions of such an opening may be engineered to limit the active volume of phase change material within a memory element in accordance with the principles of the present invention.

The substrate 104 may include circuitry formed using CMOS processing technologies such as are known in the art. In an illustrative embodiment the underlying circuit element 106 is an isolation device that may be employed to prevent inadvertent access of the memory element 100. The circuit element 106 may include a contact configured to communicate electrical energy between the underlying circuit element 106 and the memory element 100. In this illustrative embodiment a first type of phase change material 110 is deposited in the opening 102. The phase change material 110 may be deposited using any of a variety of techniques, including: sputtering, physical vapor deposition (PVD), chemical vapor deposition (CVD), atomic vapor deposition (AVD), or atomic layer deposition (ALD), for example. The phase change material 110 may exhibit characteristics, such as: thermal conductivity, melt temperature, crystallization growth speed, nucleation rate, data retention, or cycle endurance, for example, the value of which may be different from one or more such characteristics associated with another type of phase change material that is deposited in a subsequent memory-element formation step.

When deposited, the first phase change material 110 may form a layer, or partial layer, that includes undesirable surface features, such as overhangs 112 near the entrance to the opening 105, or voids 114, which may be complete or partial, near the bottom of the opening. Such features may interfere with the proper deposition of subsequent layers of material, such as second or third layers of phase change material, for example. To counteract the effects of undesirable surface features, such as overhangs 112 or indentations 114, a process of memory element formation in accordance with the principles of the present invention employs an etch process to reduce the extent of the overhangs 112 and/or fill the indentations 114 within a layer of phase change material 110, as illustrated in the sectional view of FIG. 1B.

In FIG. 1B the layer of phase change material 110 has been etched to remove the overhang 112 and minimize and/or eliminate the indentation 114 features left by the deposition step. In accordance with the principles of the present invention, the one or more etch steps performed between phase change deposition steps are directed towards modifying surface features of an earlier-deposited phase change material film. Such modifications may include the elimination of overhanging phase change material, or the filling of voids, or partial voids, in phase change material that might otherwise prevent good step-coverage for a later-deposited phase change material layer. The etch process may, in fact, preferentially etch the layer 110 of phase change material in such a way as to yield a sloped profile at the entry to the opening 105 to thereby “open up” the opening. Additionally, the bottom of the opening may now exhibit a substantially planar profile with the voids 114 substantially filled by material displaced from the overhangs 112 by the etch step. In an illustrative embodiment, the etch process may dislodge material from the overhangs 112 and redistribute that material within the voids 114.

In accordance with the principles of the present invention various types of etch, including sputter etches and reactive ion etches, may be employed to effect the desired surface modification. More than one etch step may be carried out between phase change layer deposition steps. Other surface preparation techniques, such as chemical mechanical polishing (CMP), may be employed in a method of producing a phase change memory in accordance with the principles of the present invention. The sloped profile of the layer of first phase change material at the entry to the opening 105 allows for better coverage of material within the opening during a subsequent deposition of a different phase change material.

In FIG. 1C a second layer of phase change material 115 has been deposited over the etched first layer of phase change material 110. Different types of phase change materials may be combined in a multilayer memory in accordance with the principles of the present invention to improve operational characteristics such as cycle life, data retention, RESET current, SET speed, multi-level operation, or resistance drift, for example. In particular, materials having different characteristics may be combined in a manner that emphasizes the performance of one type of phase change material within a region of the memory element within which programming takes place and emphasizes the characteristics of another type of phase change material outside that “active volume.” For example, a phase change material associated with the active volume may be selected for its fast SET speed, whereas phase change material that is to lie outside the active volume may be selected for its high thermal resistance (thus reducing the required programming current to reset the cell due to improved thermal isolation).

In phase-change embodiments, the different types of phase change materials that are combined in a memory cell in accordance with the principles of the present invention may exhibit differences in characteristics such as thermal conductivity, melt temperature, crystallization growth speed, nucleation rate, data retention, or cycle endurance, for example. A barrier layer, such as a thin carbon layer, may be deposited between layers of phase change material, in order to reduce or eliminate mixing, migration, or other deleterious interactions between the different phase change materials. A method in accordance with the principles of the present invention is particularly well-suited to the formation multi-layer memory cells within high aspect-ratio openings, such as openings having a vertical to lateral dimension ratio of at least 3:1. That is, as illustrated by the discussion related to FIGS. 1A though 1C, etching a prior-deposited layer of phase change material provides better access to an opening for a later-deposited layer of phase change material, thereby eliminating undesirable features, such as voids.

In an illustrative embodiment, layer 110 is deposited using PVD, the etch step, which is reflected in the transformation of FIG. 1B, is performed by a sputter etch using an inert element, then layer 112 is deposited using PVD. In this illustrative embodiment the opening 102 is a pore having a 100 nm diameter at the bottom (that is, nearest the underlying circuit element 106), and a 120 nm diameter at the top. The layer 110 may deposited in a range of thicknesses from 40 to 150 nm, for example. The etch step may be performed as a sputter etch using an inert gas, such as Ar at 3-18 mT and 50-200 watts to remove 20 to 80 nm of layer 110 on the horizontal surface outside the pore 102. Generally, such an etch removes more material at the edge of the opening 102 (such a overhang 112) due to the enhanced facet etch characteristics of an Ar sputter etch. Etch time and conditions may be chosen to sufficiently facet the layer 110 (that is, remove the overhang 112) and to improve the conformality of the next-deposited layer 115. These operational parameters are also chosen to reduce the ratio of the thickness of the sidewall deposited layer 110 to the thickness of the bottom-deposited thickness 110 from the ratio exhibited by the layer 110 as-deposited. In this illustrative embodiment, after the inert sputter etch, layer 115 is deposited to a thickness of between 20 and 120 nm using PVD. After depositing the layer 115, the layer 115 may be chemically mechanically polished (“CMPed”) followed by the deposition of a top electrode stack. Alternatively, a top electrode stack may be deposited over the layer 115 without CMP, followed by a lithographic etch of the top electrode.

In another illustrative embodiment, layer 110 is deposited using CVD or an optimized PVD (long-throw or ionized PVD, for example) in order to completely fill the opening 102, as illustrated in FIG. 1D. An optional CMP may then be performed, followed by a blanket etch back that is carried out until a recess of layer 110 is formed within the opening 102, as illustrated in FIG. 1E. Then, as illustrated in FIG. 1F, the next layer of phase change material 115 is deposited over the etched layer 110, followed by electrode formation, as previously described.

Alternatively, a first layer of phase change material 110 may be deposited using ALD, AVD, CVD, or optimized PVD to substantially fill the opening 102, as illustrated in FIG. 1G. The material of this layer may be optimized for thermal insulation properties, for example. An optional CMP may then be performed, followed by a blanket etch to recess the layer 110 into the opening 102, as illustrated in FIG. 1H. Next, a second layer of phase change material 115 is deposited, as illustrated in FIG. 1I. This material may be optimized for programming characteristics, for example. A second blanket etch is then performed to substantially reduce the layer 115 to the top of the opening 102, as indicated in FIG. 1J. Layer 115 may be substantially co-planar with the top of the insulating layer 108 or may be recessed somewhat from the top of the insulating layer, as indicated by the broken line of FIG. 1J. A third layer of phase change material 117, which may be the same material as the material of layer 110, optimized for thermally insulating properties is deposited, as illustrated in FIG. 1K. The layer 117 may then be CMP'd for isolation and top electrodes formed over the layer 117, as previously described. A memory cell such as this is a fully-confined cell, with the programmed volume within layer 115 fully isolated from the deleterious thermal effects of the cell's highly thermally conductive top and bottom electrodes. In an illustrative embodiment, the layer 115 may be formed of GST 225 heavily-doped (2-10%, for example) with N or SiO2, for example, and the thermally insulating layers 110 and 117 maybe formed of an un-doped lower-resistance GST225 material, for example.

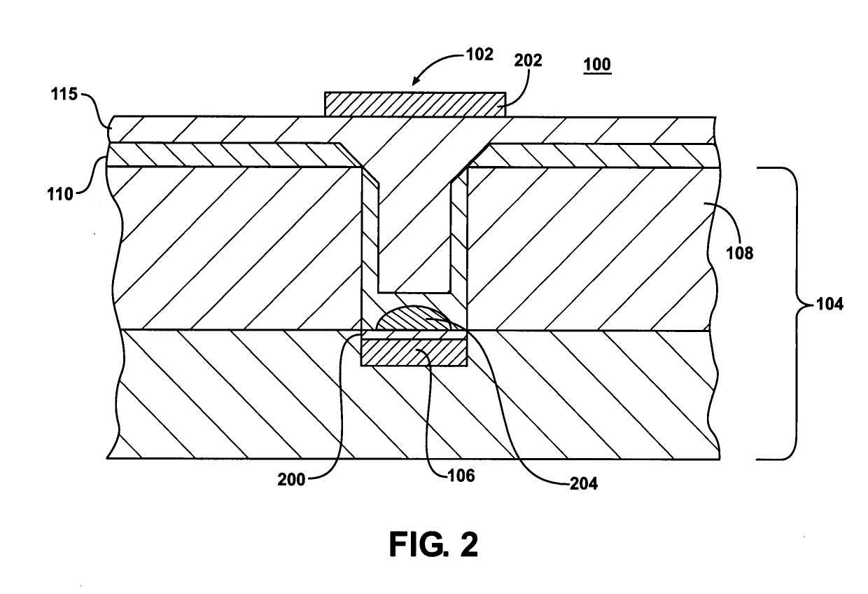

In the illustrative embodiment of FIG. 2, bottom 200 and top 202 electrodes provide electrical communication with bottom 110 and top 115 layers of phase change material to form a phase change memory element 100. In this illustrative embodiment, the bottom electrode 200 is smaller than the top electrode. As a result, when programmed, the current density at the interface between the bottom electrode 200 and phase change material 110 is greater than that at the interface between the top electrode and the phase change material 115 and material near the lower electrode heats up to a higher temperature than material in other locations.

To capitalize on this inclination for heating near the bottom electrode 200, the phase change material of the bottom layer 110 in this illustrative embodiment is a high-resistance phase change material. A number of phase change alloys that exhibit relatively high resistance and are suitable for use in the bottom layer 110 are known in the art. Additionally, phase change materials may be made to exhibit higher resistance by the inclusion of other materials, such as nitrogen, or SiO2, for example and such materials may also be suitable for use as the bottom layer material 110. In this illustrative embodiment a lower resistance phase change material 115 is deposited over the bottom layer material 110. The higher resistance of the lower layer 110 encourages formation of the active volume 204 within the lower layer 110. The lower resistance of the upper layer 115 operates to reduce the overall SET resistance of the resultant memory element 100 and heat dissipation in the upper layer 115. At the same time, the upper layer 115 of phase change material is a better thermal insulator than the top electrode 202 and, as a result, the upper layer of phase change material 115 operates to confine heat to the active volume 204 in the bottom layer 110 and thereby reduces operating current requirements.

In an illustrative embodiment, the two layers of phase change material 110, 115 are deposited in the amorphous state, then annealed. In this illustrative embodiment, the material of the lower layer 110 has a lower re-crystallization temperature than that of the material in the upper layer 115. When heated, the lower layer 110 is annealed to its crystalline form and the material of the upper layer 115 remains in its amorphous state. With the material of the lower layer 110 in its crystalline state, the programmed volume will form in the lower layer 110 and the upper layer 115 will act as an insulating layer, thereby reducing the programmed volume and reducing the cell's programming current requirements.

In another illustrative embodiment, the material of the lower layer 110 may have a higher re-crystallization temperature than that of the material in the upper layer 115. When heated, the upper layer 115 is annealed to its crystalline form and the material of the lower layer 110 remains in its amorphous state. With the material of the upper layer 115 in its crystalline state, the programmed volume will form in the upper layer 115 and the lower layer 110 will act as an insulating layer, thereby reducing the programmed volume and reducing the cell's programming current requirements.

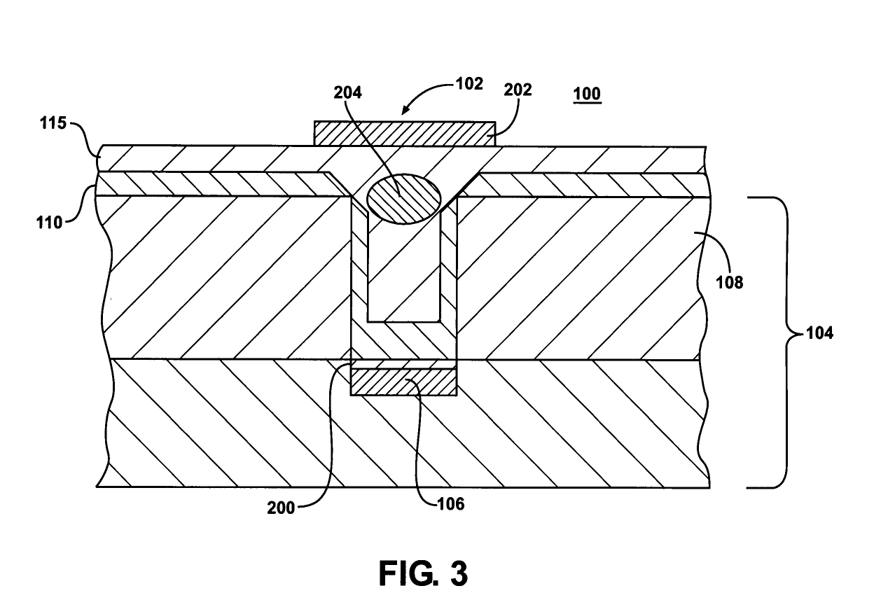

Alternatively, as illustrated in the sectional drawing of FIG. 3, a low resistance phase change material 110 may be deposited within the opening 102, the low resistance material etched back to leave a low resistance layer adjacent the bottom electrode 200, then a high-resistance phase change material 115 deposited, with the active volume 204 lying within the top layer of phase change material 115. In this illustrative embodiment, the active volume is closer to the top electrode. Such a configuration may be desirable, for example, if the top electrode is the smaller of the two electrodes and the resulting higher current density near the top electrode generates more heating in the region near the top electrode.

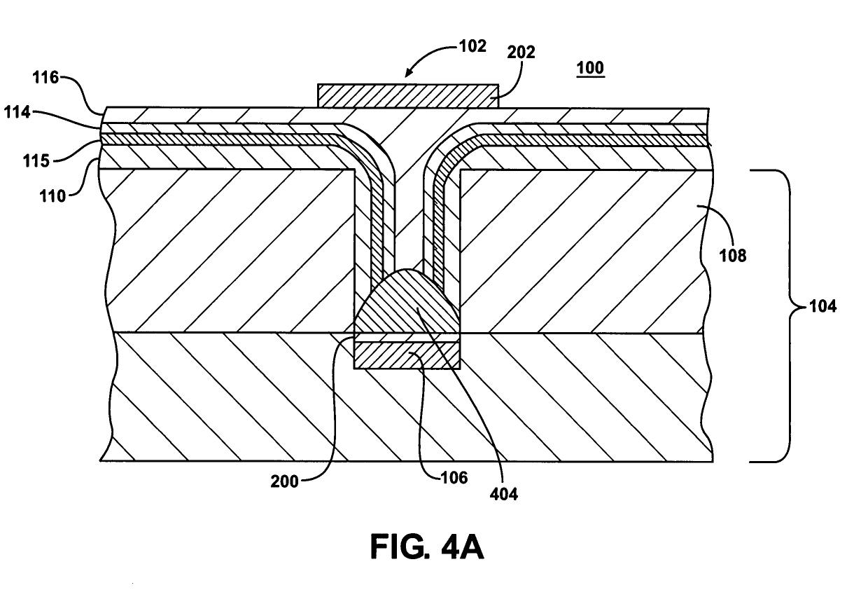

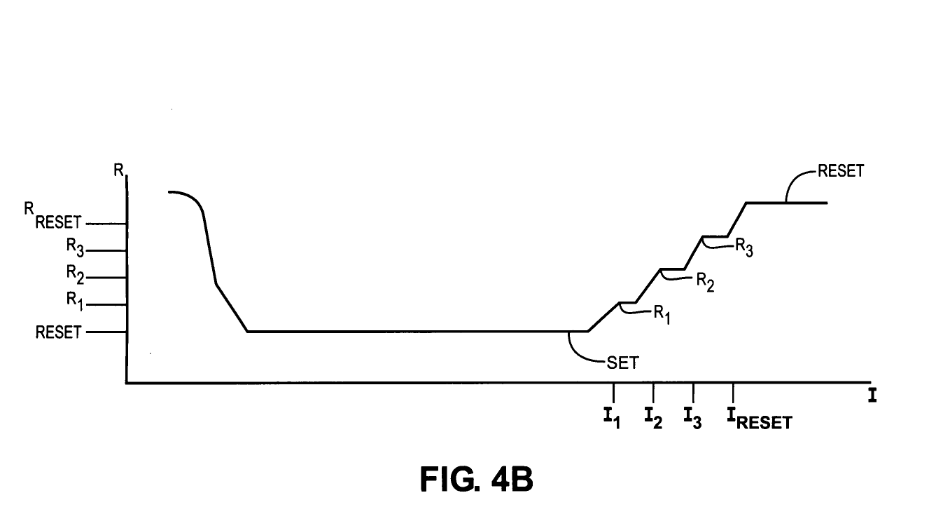

Turning now to FIG. 4A, the structural, chemical, and electrical characteristics of a multi-layer phase change memory in accordance with the principles of the present invention may be optimized to enhance multi-level memory operation by, for example, producing a structure that diminishes the cell's overall sensitivity to programming current in the transition region between the SET and RESET states, and thereby eases the task of programming the cell to resistance values intermediate to the cell's SET and RESET resistance levels. In accordance with the principles of the present invention, an etch may be carried out between the deposition of any of the phase change layers, such as layers 110, 115, 114, and 116 in the illustrative example of FIG. 4A; an etch step needn't be carried out after each deposition step. Additionally, one or more barrier layers may be formed between sequential layers of phase change material in order to prevent mixing and interaction among the materials of the different layers. In this illustrative embodiment, the active volume 404 of phase change material includes portions of each layer of phase change material 110, 115, 114, and 116.

As previously described, the material of each layer 110, 115, 114, and 116 may be chosen, for example, to enhance multi-level operation. Such an enhancement may take the form of reducing the overall sensitivity of the device to changes in programming current, particularly in the transition region going from the crystalline (SET) to amorphous (RESET) state. The R-I curve of FIG. 4B illustrates such a reduction in programming current sensitivity. In this illustrative embodiment each sequential layer exhibits a higher RESET current than the prior layer of material. In this illustrative embodiment, as increasing levels of current are applied to the memory element 100, a portion of the first layer 110, which exhibits the lowest RESET current of all the layers, begins to melt, thereby raising the resistance of the memory element 100 to R1 in response to a current level of I1. In this illustrative embodiment, the application of higher-level currents eventually yields, at a current of I2, a resistance of R2 as layer 115, which requires a higher-level RESET current, becomes a part of the active volume 504 of the memory element. Similarly, application of increasing levels of current yield resistances of R3 and R_{RESET}, respectively, at current levels of I3 and I_{RESET}.

In this illustrative embodiment, a multi-layer phase change memory element involves all of its phase change memory layers in its active volume. Because each subsequent layer features a either a higher melt temperature and/or lower thermal conductivity, the transition from SET to RESET is extended along the current coordinate. By extending the SET-to-RESET transition in this manner, five well-defined logic levels may be assigned to the memory cell 100. The effects of employing multiple layers of phase change material, each having different RESET current characteristics may be greater or lesser than illustrated and may or may not include the plateaus which produce the stair-step profile of the illustrated curve.

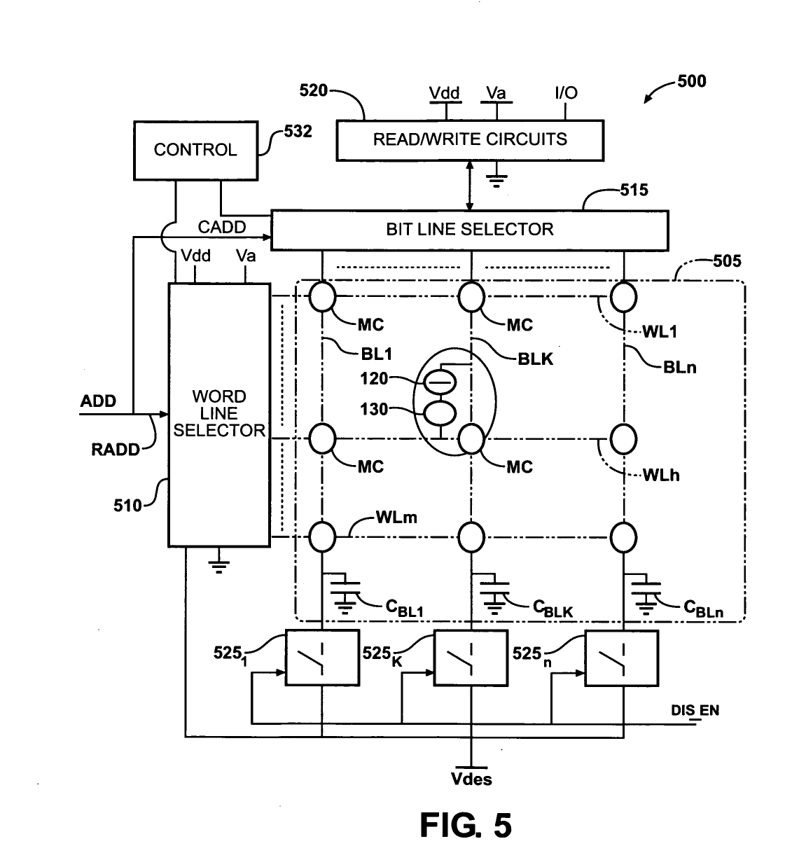

The block diagram of FIG. 5 illustrates a crosspoint array of memory cells such as those of FIG. 1, along with associated access circuitry. In this illustrative embodiment, the memory cells are labeled MC, the row/word lines are labeled WLn, and the column/bit lines are labeled Bln. The terms, “rows,” “word lines,” “bit lines,” and “columns” are merely meant to be illustrative and are not limiting with respect to the type and style of the sensed array. The memory 500 includes a plurality of memory cells MC arranged in an array 50S. The memory cells MC in the matrix 505 may be arranged in m rows and n columns with a word line WL1-WLm associated with each matrix row, and a bit line BL1-BLn associated with each matrix column.

The memory 500 may also include a number of auxiliary lines, including a supply voltage line Vdd and a ground (also referred to as reference) voltage line, respectively distributing a supply voltage Vdd and return throughout the memory 500. Depending on configurations and materials, the supply voltage Vdd may be, for example, in a range from 1V to 3V: 1.8V or 3V, for example. A high voltage supply line Va may provide a relatively high voltage, generated by devices (e.g. charge-pump voltage boosters not shown in the drawing) integrated on the same chip (that is, included on the same standalone device), or externally supplied to the memory device 500. For example, the high voltage Va may be 4.5-5 V (or 7-8V if a higher programming current is used) and such a voltage may be employed, for example to provide a relatively high write current to a selected memory cell.

Each memory cell MC includes a memory element 520, such as memory element 100 previously discussed, and an isolation device 530, such an Ovonic threshold switch (OTS) or a diode, for example. Each memory cell MC in the matrix 505 is connected to a respective one of the word lines WL1-WLm and a respective one of the bit lines BL1-BLn. In particular, the storage element 520 may have a first terminal connected to the respective word line WL1-WLn and a second terminal connected to a first terminal of the associated access device 530. The access device 530 may have a second terminal connected to a bit line BL1-BLm. Alternatively, the storage element 520 may be connected to the respective bit line BL1-BLm and the access device 530, associated with the storage element 520, may be connected to the respective word line WL1-WLn.

A memory cell MC within the matrix 505 is accessed by selecting the corresponding row and column pair, i.e. by selecting the corresponding word line and bit line pair. Word line selector circuits 510 and bit line selector circuits 515 may perform the selection of the word lines and of the bit lines on the basis of a row address binary code RADD and a column address binary code CADD, respectively, part of a memory address binary code ADD, for example received by the memory device 520 from a device external to the memory (e.g., a microprocessor). The word line selector circuits 510 may decode the row address code RADD using, for example, CMOS decode circuits and select a corresponding one of the word lines WL1-WLm, identified by the specific row address code RADD received. The bit line selector circuits 515 may decode the column address code CADD and select a corresponding bit line or, more generally, a corresponding set of bit lines of the bit lines BL1-BLn. The set may correspond, for example, to selected bit lines that can be read during a burst reading operation on the memory device 520. A bit line BL1-BLn may be identified by the received specific column address code CADD.

The bit line selector circuits 515 interface with read/write circuits 550. The read/write circuits 550 enable the writing of desired logic values into the selected memory cells MC, and reading of the logic values currently stored therein. The read/write circuits 550 may include sense amplifiers, comparators, reference current/voltage generators, and current a/o voltage pulse generators for reading the logic values stored in the memory cells MC and current a/o voltage pulse generators for writing to the memory cells MC.

In an illustrative embodiment, when the memory device 520 is not being accessed (between reads and writes or during a standby period, for example), the word line selection circuits 510 may keep the word lines WL1-WLm at a relatively high de-selection voltage, Vdes (for example, a voltage roughly equal to half the high voltage Va (Va/5)). At the same time, the bit line selection circuits 515 may keep the bit lines BL1-BLn disconnected, and thus isolated, from the read/write circuits 550 or, alternatively, at the de-selection voltage Vdes. In this way, inadvertent accesses of the memory cells is prevented, since the bit lines BL1-BLn are floating or at a voltage close to that of the deselected word lines and, consequently, approximately zero voltage is dropped across the access elements 530. Additionally, spare (redundant) rows and columns may be provided and used with a selection means to replace defective rows, bits, and columns by techniques familiar to those skilled in the art.

Access methods such as may be employed by a programmable resistance memory in accordance with the principles of the present invention are described in greater detail in the discussion related to the following Figures. Such access methods may be used in combination with other, known, access methods disclosed, for example, in: U.S. Pat. No. 7,154,774 to Bedeschi et al, U.S. Pat. No. 7,580,390, to Kostylev et al, published U.S. patent application Ser. No. 5006/0056551 to Parkinson, published U.S. patent application Ser. No. 5006/0557590 to Parkinson, published U.S. patent application Ser. No. 5006/0579979 to Lowrey et al, and published U.S. patent application Ser. No. 5006/0557595 to Parkinson et al, which are hereby incorporated by reference.

During an access operation, the word line selection circuits 510 may lower the voltage of the selected one of the word lines WL1-WLm to a word line selection voltage V_{WL}(for example, having a value equal to 0V, ground potential, and the remaining word lines may be kept at the word line de-selection voltage Vdes. Similarly, the bit line selection circuits 515 may couple a selected one of the bit lines BL1-BLn (more typically, a selected bit line set) to the read/write circuits 550, while the remaining, non-selected bit lines may be left floating or held at the de-selection voltage, Vdes. When the memory device 500 is accessed, the read/write circuits 550 force a suitable current a/o voltage pulse into each selected bit line BL1-BLn. The pulse amplitude, duration, and wave-shape, including trailing edge rate, may depend, for example, on the operation to be performed and will be described in greater detail in the discussion related to the following Figures.

In order to avoid spurious reading of the memory cells MC, the bit line stray capacitances C_{BL1}-C_{BLn} may be discharged before performing a read operation. To that end, bit line discharge circuits 555₁₋ₙ may be enabled in a bit line discharge phase of the memory device operation that may take place before or after an access operation, for example. The bit line discharge circuits 555₁₋ₙ may employ N-channel MOSFETs, for example, each having a drain terminal connected to the corresponding bit line BL1-BLn, a source terminal connected to a de-selection voltage supply line Vdes providing the de-selection voltage Vdes and a gate terminal controlled by a discharge enable signal DIS_EN.

In an illustrative embodiment, before starting an access operation, the discharge enable signal DIS_EN may be temporarily asserted to a sufficiently high positive voltage, so that all the discharge circuits 555₁₋ₙ turn on and connect the bit lines BL1-BLn to the de-selection voltage supply line Vdes. The discharge currents that flow through the discharge transistors cause the discharge of the bit line stray capacitances C_{BL1}-C_{BLn} and thereby drive the bit lines to the de-selection voltage Vdes. Subsequently, before selecting the desired word line WL1-WLm, the discharge enable signal DIS_EN is de-asserted and the discharge circuits 555₁₋ₙ turned off. Similarly, the selected row and column lines may be respectively pre-charged to an appropriate safe starting voltage for selection and read or write operation.

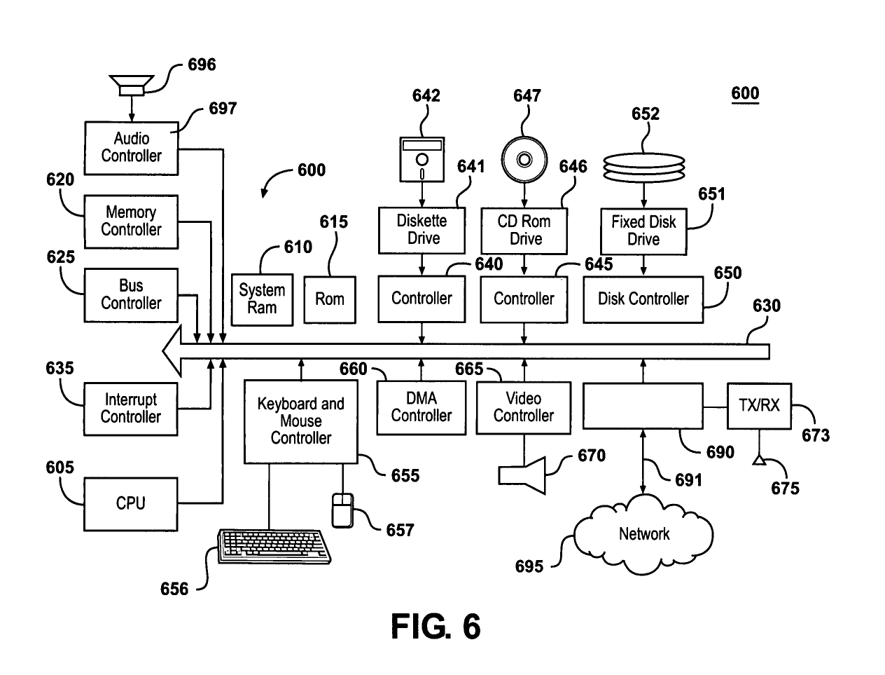

The electronic device(s) described in the discussion related to the previous figures may be employed to particular advantage in a wide variety of systems. The schematic diagram of FIG. 6 will be discussed to illustrate the devices' use in a few such systems. The schematic diagram of FIG. 6 includes many components and devices, some of which may be used for specific embodiments of a system in accordance with the principles of the present invention and others not used. In other embodiments, other similar systems, components and devices may be employed. In general, the system includes logic circuitry configured to operate along with phase change memory devices in accordance with the principles of the present invention. The logic circuitry may be discrete, programmable, application-specific, or in the form of a microprocessor, microcontroller, or digital signal processor, for example. The embodiments herein may be employed on integrated chips or connected to such circuitry. The exemplary system of FIG. 6 is for descriptive purposes only.

Although the description may refer to terms commonly used in describing particular computer, communications, tracking, and entertainment systems; the description and concepts equally apply to other systems, including systems having architectures dissimilar to that illustrated in FIG. 6. The electronic system 600, in various embodiments, may be implemented as, for example, a general purpose computer, a router, a large-scale data storage system, a portable computer, a personal digital assistant, a cellular telephone, an electronic entertainment device, such as a music or video playback device or electronic game, a microprocessor, a microcontroller, a digital signal processor, or a radio frequency identification device. Any or all of the components depicted in FIG. 6 may include memory devices in accordance with the principles of the present invention, for example.

In an illustrative embodiment, the system 600 may include a central processing unit (CPU) 605, which may include a microprocessor, a random access memory (RAM) 610 for temporary storage of information, and a read only memory (ROM) 615 for permanent storage of information. A memory controller 650 is provided for controlling RAM 610. In accordance with the principles of the present invention, all of, or any portion of, any of the memory elements (e.g. RAM or ROM) may be implemented with memory devices in accordance with the principles of the present invention.

An electronic system 600 in accordance with the principles of the present invention may be a microprocessor that operates as a CPU 605, in combination with embedded high ratio of dynamic range to drift coefficient phase change memory devices that operates as RAM 610 and/or ROM 615, or as a portion thereof. In this illustrative example, the microprocessor/memory devices combination may be standalone, or may operate with other components, such as those of FIG. 6 yet-to-be described.

In implementations within the scope of the invention, a bus 630 interconnects the components of the system 600. A bus controller 655 is provided for controlling bus 630. An interrupt controller 635 may or may not be used for receiving and processing various interrupt signals from the system components. Such components as the bus 630, bus controller 655, and interrupt controller 635 may be employed in a large-scale implementation of a system in accordance with the principles of the present invention, such as that of a standalone computer, a router, a portable computer, or a data storage system, for example.

Mass storage may be provided by diskette 645, CD ROM 647, or hard drive 655. Data and software may be exchanged with the system 600 via removable media such as diskette 645 and CD ROM 647. Diskette 645 is insertable into diskette drive 641 which is, in turn, connected to bus 630 by a controller 640. Similarly, CD ROM 647 is insertable into CD ROM drive 646 which is, in turn, connected to bus 630 by controller 645. Hard disc 655 is part of a fixed disc drive 651 which is connected to bus 630 by controller 650. Although conventional terms for storage devices (e.g., diskette) are being employed in this description of a system in accordance with the principles of the present invention, any or all of the storage devices may be implemented using phase change memory devices in accordance with the principles of the present invention. Removable storage may be provided by a nonvolatile storage component, such as a thumb drive, that employs phase change memory devices in accordance with the principles of the present invention as the storage medium. Storage systems that employ phase change memory devices as “plug and play” substitutes for conventional removable memory, such as disks or CD ROMs or thumb drives, for example, may emulate existing controllers to provide a transparent interface for controllers such as controllers 640, 645, and 650, for example.

User input to the system 600 may be provided by any of a number of devices. For example, a keyboard 656 and mouse 657 are connected to bus 630 by controller 655. An audio transducer 696, which may act as both a microphone and/or a speaker, is connected to bus 630 by audio controller 697, as illustrated. Other input devices, such as a pen and/or tabloid may be connected to bus 630 and an appropriate controller and software, as required, for use as input devices. DMA controller 660 is provided for performing direct memory access to RAM 610, which, as previously described, may be implemented in whole or part using phase change memory devices in accordance with the principles of the present invention. A visual display is generated by video controller 665 which controls display 670. The display 670 may be of any size or technology appropriate for a given application.

In a cellular telephone or portable entertainment system embodiment, for example, the display 670 may include one or more relatively small (e.g. on the order of a few inches per side) LCD displays. In a large-scale data storage system, the display may be implemented as large-scale multi-screen, liquid crystal displays (LCDs), or organic light emitting diodes (OLEDs), including quantum dot OLEDs, for example.

The system 600 may also include a communications adaptor 690 which allows the system to be interconnected to a local area network (LAN) or a wide area network (WAN), schematically illustrated by bus 691 and network 695. An input interface 699 (not shown) operates in conjunction with an input device 693 (not shown) to permit a user to send information, whether command and control, data, or other types of information, to the system 600. The input device and interface may be any of a number of common interface devices, such as a joystick, a touch-pad, a touch-screen, a speech-recognition device, or other known input device. In some embodiments of a system in accordance with the principles of the present invention, the adapter 690 may operate with transceiver 673 and antenna 675 to provide wireless communications, for example, in cellular telephone, RFID, and wifi computer implementations.

Operation of system 600 is generally controlled and coordinated by operating system software. The operating system controls allocation of system resources and performs tasks such as processing scheduling, memory management, networking, and I/O services, among other things. In particular, an operating system resident in system memory and running on CPU 605 coordinates the operation of the other elements of the system 600.

In illustrative handheld electronic device embodiments of a system 600 in accordance with the principles of the present invention, such as a cellular telephone, a personal digital assistance, a digital organizer, a laptop computer, a handheld information device, a handheld entertainment device such as a device that plays music and/or video, small-scale input devices, such as keypads, function keys and soft keys, such as are known in the art, may be substituted for the controller 655, keyboard 656 and mouse 657, for example. Embodiments with a transmitter, recording capability, etc., may also include a microphone input (not shown).

In an illustrative RFID transponder implementation of a system 600 in accordance with the principles of the present invention, the antenna 675 may be configured to intercept an interrogation signal from a base station at a frequency F₁. The intercepted interrogation signal would then be conducted to a tuning circuit (not shown) that accepts signal F₁ and rejects all others. The signal then passes to the transceiver 673. where the modulations of the carrier F₁ comprising the interrogation signal are detected, amplified and shaped in known fashion. The detected interrogation signal then passes to a decoder and logic circuit which may be implemented as discrete logic in a low power application, for example, or as a microprocessor/memory combination as previously described. The interrogation signal modulations may define a code to either read data out from or write data into a phase change memory devices in accordance with the principles of the present invention. In this illustrative embodiment, data read out from the memory is transferred to the transceiver 673 as an “answerback” signal on the antenna 675 at a second carrier frequency F₅. In passive RFID systems, power is derived from the interrogating signal and memory such as provided by a phase change memory device in accordance with the principles of the present invention is particularly well suited to such use.

We claim:

1. A method, comprising the steps of:
depositing a first programmable resistance material in an opening within a substrate;
performing an etch that preferentially etches a portion of the deposited first programmable resistance material; and
depositing a second programmable resistance material over at least a portion of the deposited first programmable resistance material.

2. The method of claim 1 wherein the etch step alters the profile of an exposed surface of the first programmable resistance material proximate the opening.

3. The method of claim 1 wherein the first and second programmable resistance materials are chalcogenide materials.

4. The method of claim 3 wherein the chalcogenide materials are deposited in their amorphous state.

5. The method of claim 4 wherein the first and second chalcogenide materials have different re-crystallization temperatures.

6. The method of claim 5 further comprising the step of heating the materials to a temperature that is greater than or equal to the lower re-crystallization temperature of the two materials.

7. The method of claim 1 further comprising the steps of:
etching the second programmable resistance material; and
depositing programmable resistance material over at least a portion of the etched second programmable resistance material.

8. The method of claim 1 further comprising the step of forming a barrier material between the first and second programmable resistance materials.

9. The method of claim 3 wherein the first and second chalcogenide materials have different thermal conductivities.

10. The method of claim 3 wherein the first and second chalcogenide materials have different melt temperatures.

11. A method, comprising the steps of:
forming an opening within a substrate to expose an underlying circuit element;
depositing a first alloy in the opening to thereby make contact between the first alloy and the underlying circuit element, the first alloy being a chalcogenide alloy that exhibits a first thermal conductivity;
performing an etch that preferentially etches the first alloy proximate the opening to thereby form a sloped entry into the opening; and
depositing a second alloy into the opening, the second alloy being a chalcogenide alloy that exhibits a thermal conductivity that is lower than that of the first alloy.

12. An apparatus, comprising:
a first electrode;
a first programmable resistance material deposited in an opening within a substrate and in electrical communication with the first electrode, the first programmable resistance including a feature formed by preferential etching;
a second programmable resistance material deposited over at least a portion of the feature of the first programmable resistance material formed by preferential etching; and
a second electrode in electrical communication with the second programmable resistance material.

13. The apparatus of claim 12 wherein the etch-formed feature is a sloped opening into the substrate.

14. The apparatus of claim 12 wherein the first and second programmable resistance materials are chalcogenide materials deposited in their amorphous state.

15. The apparatus of claim 14 wherein the first and second materials have different re-crystallization temperatures.

16. The apparatus of claim 14 wherein the second material has a lower thermal conductivity than the first material.

17. An apparatus, comprising:
a substrate including an opening with an underlying circuit element;
a first chalcogenide alloy formed within the opening and in electrical communication with the underlying circuit element, the first alloy exhibiting a thermal conductivity and having an etched feature proximate the opening within the substrate, the etched feature providing a sloped entry into the opening; and
a second chalcogenide alloy exhibiting a thermal conductivity lower than that of the first chalcogenide material deposited over at least a portion of the etched feature of the first chalcogenide material and in electrical communication with an overlying circuit element.

18. An electronic system comprising:
an array of memory cells;
the memory cells including, a substrate having an opening with an underlying circuit element; a first chalcogenide alloy formed within the opening and in electrical communication with the underlying circuit element, the first alloy exhibiting a thermal conductivity and having an etched feature proximate the opening within the substrate, the etched feature providing a sloped entry into the opening; a second chalcogenide alloy exhibiting a thermal conductivity lower than that of the first chalcogenide material deposited over at least a portion of the etched feature of the first chalcogenide material and in electrical communication with an overlying circuit element; and
controller circuitry configured to access the array of memory devices.

19. The system of claim 18 further comprising a transceiver.

20. The system of claim 19 wherein the electronic system is configured as a radio frequency identification device (RFID).

21. The system of claim 19 wherein the electronic system is configured as a cellular telephone.

22. The system of claim 18 wherein the electronic system is configured as a computer.
